(19) United States
(12) Patent Application Publication
(10) Pub. No.: US 2005/0257821 A1
(43) Pub. Date: Nov. 24, 2005

(54) Thermoelectric nano-wire devices

(76) Inventors: Shriram Ramanathan, Hillsboro, OR (US); Gregory M. Chrysler, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/849,964

(22) Filed: May 19, 2004

(51) Int. Cl. H01L 23/52; F25B 21/02

(52) U.S. Cl. 136/203; 257/930; 62/3.2

(57) ABSTRACT

Apparatus and method of fabricating a heat dissipation device that includes at least one thermoelectric device fabricated with nano-wires for drawing heat from at least one high heat area on a microelectronic die. The nano-wires may be formed from bismuth containing materials and may be clustered of optimal performance.

### BACKGROUND OF THE INVENTION

1. Field of the Invention

The present invention relates to microelectronic device fabrication. In particular, the present invention relates to incorporating a thermoelectric nano-wire device in a microelectronic assembly for cooling hot-spots in microelectronic die.

2. State of the Art

Higher performance, lower cost, increased miniaturization of integrated circuit components, and greater packaging densities of integrated circuits are ongoing goals of the computer industry. As these goals are achieved, microelectronic dice become smaller. Accordingly, the density of power consumption of the integrated circuit components in the microelectronic die has increased, which, in turn, increases the average junction temperature of the microelectronic die. If the temperature of the microelectronic die becomes too high, the integrated circuits of the microelectronic die may be damaged or destroyed.

Various apparatus and techniques have been used and are presently being used for removing heat from microelectronic dice. One such heat dissipation technique involves the attachment of a high surface area heat sink to a microelectronic die. FIG. 21 illustrates an assembly 400 comprising a microelectronic die 402 (illustrated as a flip chip) physically and electrically attached to a substrate 404 (such as an interposer, a motherboard, or the like) by a plurality of solder balls 406 extending between pads (not shown) on an active surface of the microelectronic die 402 and lands (not shown) on the substrate 404.

A high surface area heat sink 408 is attached to a back surface 412 of the microelectronic die 402 by a thermally conductive adhesive 414. The high surface area heat sink 408 is usually constructed from a thermally conductive material, such as copper, aluminum, aluminum, alloys thereof, and the like. Heat generated by the microelectronic die 402 is drawn into the heat sink 408 (following the path of least thermal resistance) by conductive heat transfer.

High surface area heat sinks 408 are generally used because the rate at which heat is dissipated from a heat sink is substantially proportional to the surface area of the heat sink. The high surface area heat sink 408 usually includes a plurality of projections 416 extending substantially perpendicularly from the microelectronic die 402. It is, of course, understood that the projections 416 may include, but are not limited to, elongate planar fin-like structures and columnar/pillar structures. The high surface area of the projections 416 allows heat to be convectively dissipated from the projections 416 into the air surrounding the high surface area heat sink 408. However, although high surface area heat sinks are utilized in a variety of microelectronic applications, they have not been completely successful in removing heat from microelectronic dice that generate substantial amounts of heat.

One issue that may contribute to this lack of success is that high power circuits are generally located close to one another within the microelectronic dice 402. The concentration of the high power circuits results in areas of high heats or “hotspots”. Current heat sink solutions merely extract heat substantially uniformly from the microelectronic die 402 and do not compensate for the hotspots. Thus, the circuitry at or proximate to these hotspots can be thermally damaged, which can severely affect reliability and long term performance.

Therefore, it would be advantageous to develop apparatus and techniques to effectively remove heat from microelectronic dice while compensating for thermal variations, such as hot spots, within the microelectronic dice.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings to which:

FIG. 1 is a side cross-sectional view of a microelectronic die having an isolation layer disposed thereon, according to the present invention;

FIG. 2 is a side cross-sectional view of a first electrode formed on the isolation layer of FIG. 1, according to the present invention;

FIG. 3 is a side cross-sectional view of a dielectric layer is disposed over the first electrode and a portion of the isolation layer of FIG. 2, according to the present invention;

FIG. 4 is a side cross-sectional view of forming nano-wires through the dielectric layer of FIG. 3, according to the present invention;

FIGS. 5 and 6 are side cross-sectional views of forming nano-wires through the dielectric layer by forming openings therein, according to the present invention;

FIGS. 7 and 8 are side cross-sectional views of forming nano-wires through voids in the dielectric layer, according to the present invention;

FIG. 9 is a cross-sectional view of forming a second electrode on the dielectric layer; according to the present invention;

FIG. 10 is a cross-sectional view of a thermoelectric nano-wire device, according to the present invention;

FIG. 11 is a cross-sectional view of a heat dissipation device contacting the thermoelectric nano-wire device with an interface, according to the present invention;

FIG. 12 is a cross-sectional view of nano-wire clusters in a thermoelectric nano-wire device, according to the present invention;

FIG. 13 is a top plan view of a microelectronic die and a thermal profile thereon, according to the present invention;

FIG. 14 is a cross-section of the density of nano-wires varied to match the thermal profile of the microelectronic die along line 14-14 of FIG. 13, according to the present invention;

FIGS. 15 and 16 are graphs illustrating the performance enhancement using nano-scale thermoelectric wires, according to the present invention;

FIG. 17 is a graph illustrating the junction temperature improvement using a thermoelectric nano-wire device, according to the present invention;

FIG. 18 is a side view of a microelectronic die attached to a substrate, according to the present invention;

FIG. 19 is an oblique view of a hand-held device having a microelectronic assembly of the present integrated therein, according to the present invention;

FIG. 20 is an oblique view of a computer system having a microelectronic assembly of the present integrated therein, according to the present invention; and

FIG. 21 is a side view of a microelectronic die attached to a substrate, as know in the art.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention comprises a heat dissipation device that includes at least one thermoelectric device fabricated with nano-wires for drawing heat from at least one high heat area (i.e., “hot spot”) on a microelectronic die. Such thermoelectric devices are known in the art and are essentially solid-state devices that function as heat pumps. An exemplary device is a sandwich formed by two electrodes with an array of small bismuth telluride cubes in between. When a low voltage direct current power source is applied between the two electrodes, heat is moved in the direction of the current from the positive electrode to the negative electrode.

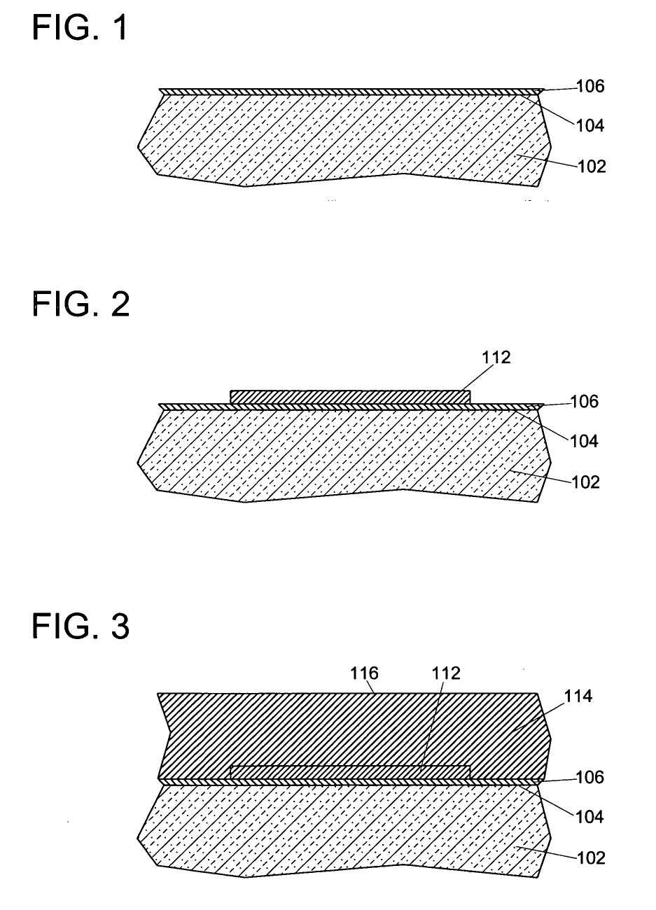

FIGS. 1 through 21 illustrate methods of fabricating thermoelectric devices and embodiments thereof, according the present invention. FIG. 1 shows a portion of a microelectronic die 102 having a heat removal surface 104. An isolation layer 106 is formed on the microelectronic die heat removal surface 104 to provide electrical isolation from the microelectronic die 102. The isolation layer 106 may be deposited or grown, by any technique known in the art, to a thickness between about 0.1 and 1.0 micron. The isolation layer 106 may be any suitable electrically insulative material, including, but not limited to, silicon dioxide, silicon nitride, and the like.

FIG. 2 illustrates the fabrication of a first electrode 112 on the isolation layer 106. The first electrode 112 can be made by any method known in the art including, but not limited to, photolithography. The first electrode 112 may be any appropriate conductive material such as copper, aluminum, gold, silver, alloys thereof, and the like.

As shown in FIG. 3, a dielectric layer 114 is disposed over the first electrode 112 and a portion of the isolation layer 106. The dielectric layer 114 may include, but is not limited to, porous materials, such as porous silicon dioxide, porous alumina, and the like. Porous alumina films can be grown using methods such as anodization, as will be understood to those skilled in the art.

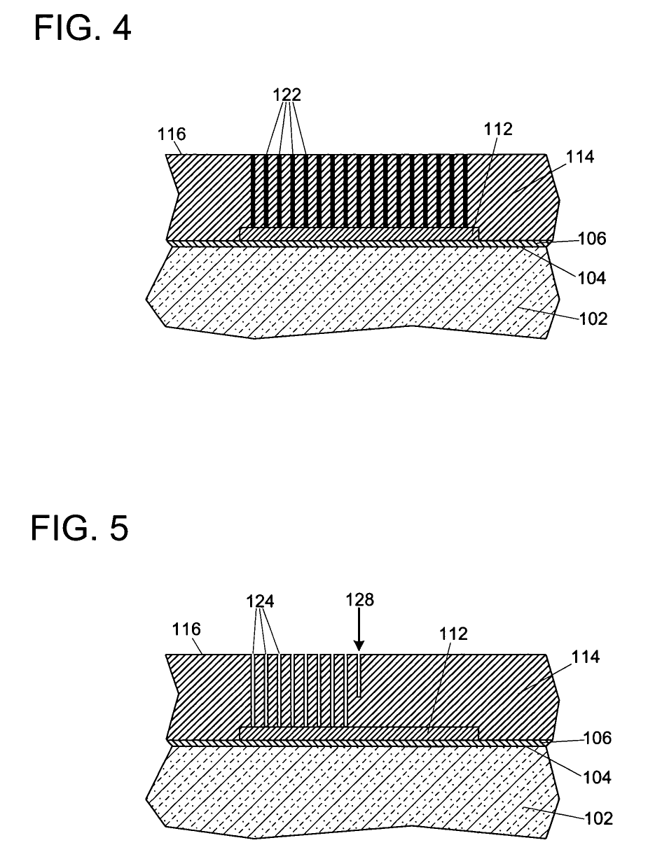

FIG. 4 illustrates at least one nano-wire 122 extending from a first surface 116 of the dielectric layer 114 through the dielectric layer 114 to contact the first electrode 112. The term “nano-wire” is defined as a wire which has a diameter, measured on the nanometer scale, of approximately 1000 nanometers or less. In one embodiment, the nano-wires 122 may have a diameter of between about 1 and 100 nm. Preferably, the nano-wires 122 are substantially perpendicular to the first electrode 112.

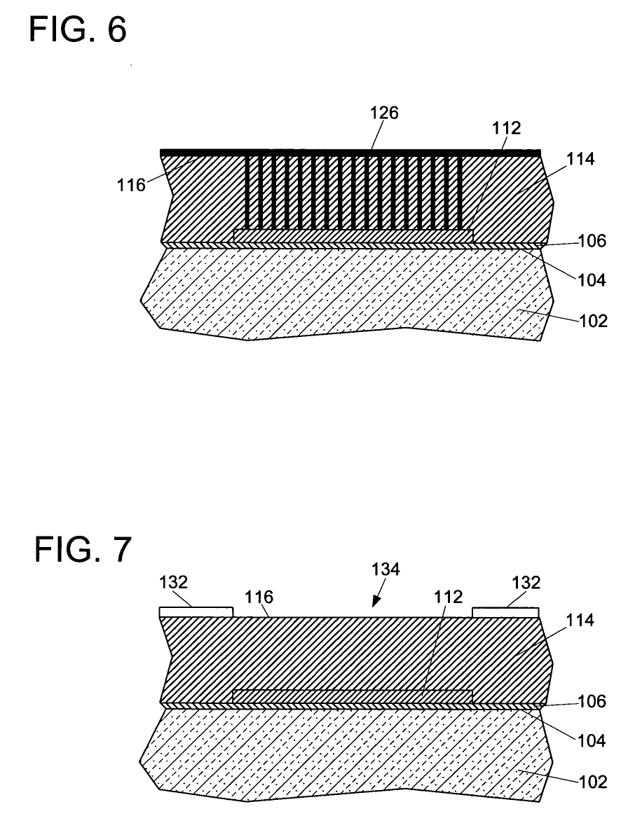

As illustrated in FIG. 5, the nano-wires 122 (see FIG. 4) can be fabricated by forming nano-scale openings 124 from the dielectric layer first surface 116 through the dielectric layer 114 to the first electrode 112, such as by e-beam milling (illustrated as arrow 128) or the like, as will be understood by those skilled in the art. A conductive material 126 is deposited over the dielectric layer 114, such that the conductive material 126 fills the nano-scale openings 124 to contact the first electrode 112, as shown in FIG. 6. The conductive material 126 may be deposited by any technique known in the art, including, but not limited to electrodeposition, sputtering, chemical vapor deposition, and the like. The nano-wires 122 may be fabricated from any appropriate material, including, but not limited to, bismuth containing materials (including substantially pure bismuth, bismuth telluride, and the like). Excess conductive material 126 is removed, such as by etching or polishing, leaving the conductive material 126 within the nano-scale openings 124 (see FIG. 5) to form the discrete nano-wires 122, such as shown in FIG. 4.

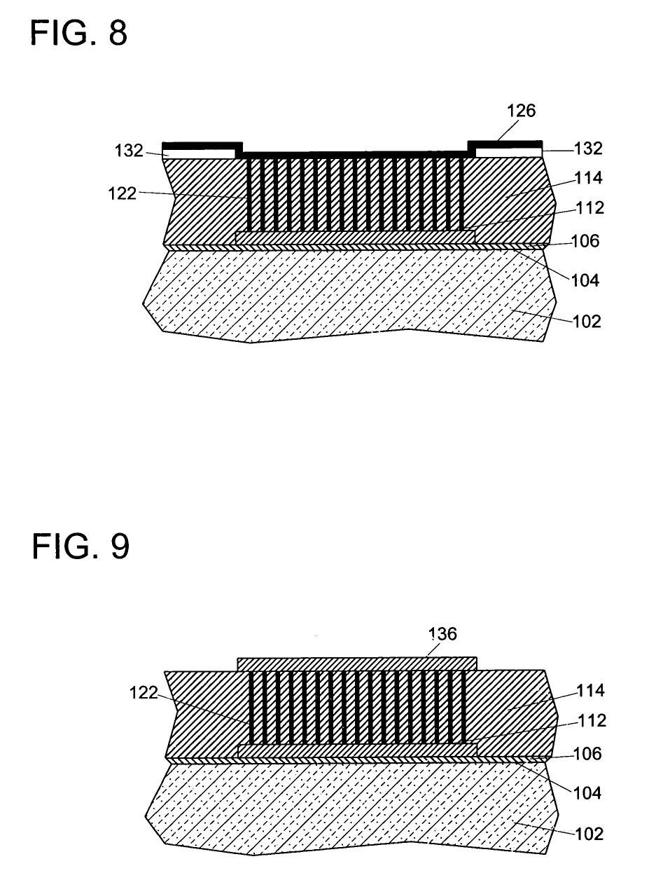

If a porous material is used for the dielectric layer 114, the material used for the nano-wires 122 may be deposited directly on the dielectric layer 114, wherein the material extends through the voids in the porous dielectric layer 114. For example, as shown in FIG. 7, a mask 132, such as a photoresist, can be patterned on the dielectric layer 114 with a mask opening 134 opposing the first electrode 112 across the dielectric layer 114. The conductive material 126 is deposited over the mask 132 and into the mask opening 134 to contact a portion of the dielectric layer 114 and extends through the voids (not shown) in the porous dielectric layer 114 to contact the first electrode 112, as shown in FIG. 8. Excess conductive material 126 and the mask 132 are removed, such as by etching or polishing, leaving the conductive material 126 within the voids to form the discrete nano-wires 122, such as shown in FIG. 4.

FIG. 9 illustrates a second electrode 136 formed on the dielectric material first surface 116 contacting the nano-wires 122. The second electrode 136 can be made by any method known in the art including, but not limited to, photolithography. The second electrode 136 may be any conductive material such as copper, aluminum, gold, silver, alloys thereof, and the like.

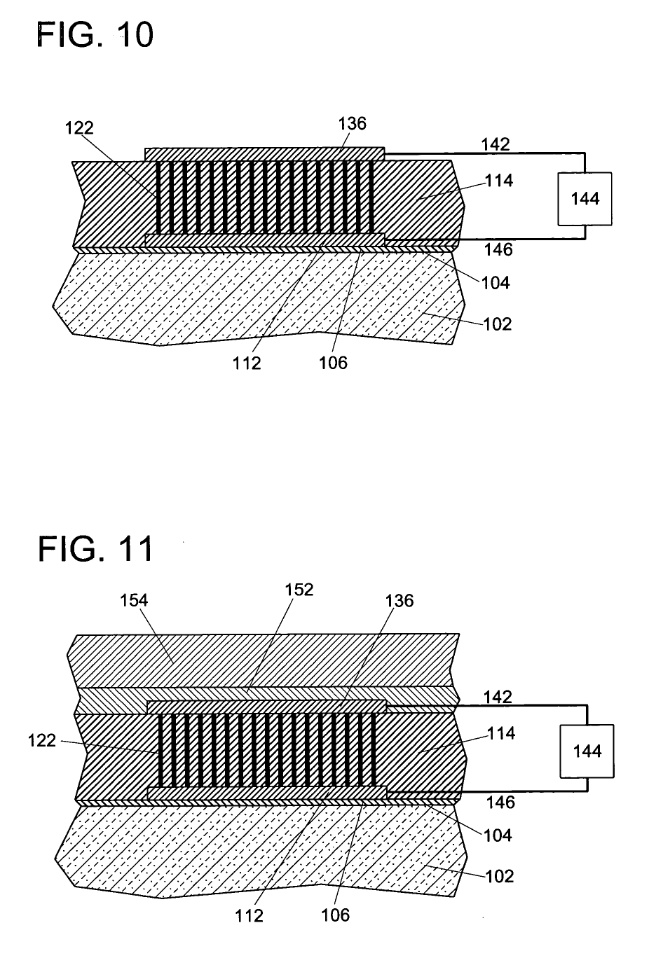

FIG. 10 illustrates a completed thermoelectric nano-wire device 140, wherein a negatively charged trace (shown as line 142) extending from a direct current power source 144 may be connected to the second electrode 136 and a positively charged trace (shown as line 146) extending from the direct current power source 144 may be connected to the first electrode 112. Thus, heat is moved in the direction of the current flow from the first electrode 112 to the second electrode 136. It is, of course, understood that the positively charged trace 146 and the negatively charged trace 142 may be fabricated during the formation for the first electrode 112 and the second electrode 136, respectively.

As shown in FIG. 11, an interface 152 may be place over the second electrode 136 and portions of the dielectric material 114, and a heat dissipation device 154, such as a heat slug, finned heat sink, or the like, may be placed on the thermal interface material 152 to remove heat delivered to the second electrode 136 and spread the heat away from the microelectronic die 102. The interface 152 may be a thermal interface material, a heat sink formed (such as depositing metal, e.g., copper) in contact with the second electrode 136, or the like. The heat dissipation device 154 may be any thermally conductive material including, but not limited to, copper, copper alloys, aluminum, aluminum alloys, and the like. In such a configuration, if the interface 152 and/or heat dissipation device 154 is electrically conductive, the negatively charged trace 142 may be connected to the interface 152 and/or heat dissipation device 154, which will serve to complete the circuit for the thermoelectric nano-wire device 140.

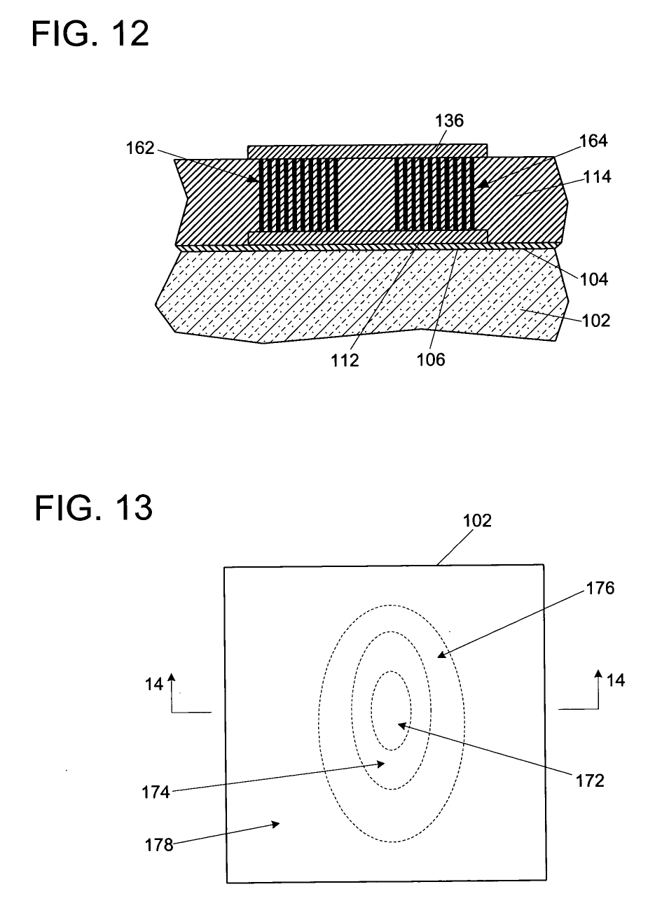

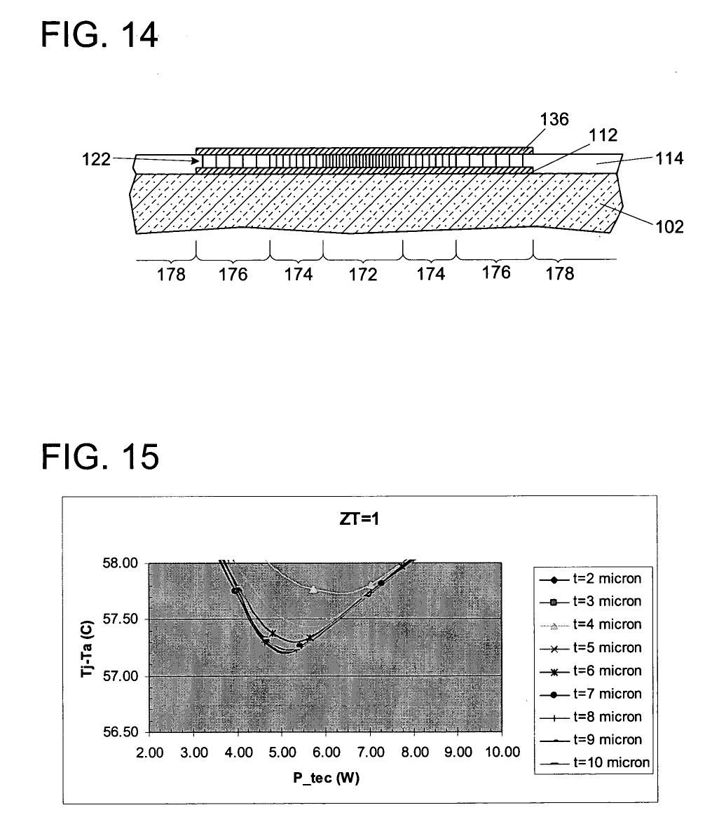

It is, of course, understood that a plurality of thermoelectric nano-wire devices 140 could be distributed as needed over the microelectronic die 102. Furthermore, as shown in FIG. 12, multiple nano-wire clusters, for example clusters 162 and 164 could be disposed between a single first electrode 112 and a single second electrode 136. Furthermore, the thermoelectric nano-wire device can be tuned for a specific thermal profile on the microelectronic die. As shown in FIG. 13 (a top view of the microelectronic die 102), the microelectronic die 102 may have a thermal profile, as shown, with a high heat area 172, a medium heat area 174 surrounding the high heat area 172, a low heat area 176 surrounding the medium heat area 174, and a cooler area 178 across the remainder of the microelectronic die 102. As shown in FIG. 14, the nano-wires 122 can be densely configured in the high heat area 172, less densely configured in the medium heat area 174, still less densely configured in the low heat area 176, and not distributed in the cooler area 178. The densely configured nano-wires remove a greater amount of heat than the less densely configured areas. Thus, the thermoelectric nano-wire device 170 can be tuned for specific applications.

The low dimensionality of nano-wires (i.e., close to one-dimensional) has been found to enhance thermoelectric properties of the device and hence can result in more efficient cooling than known thermoelectric coolers.

The present invention has several advantages over known cooling system, potentially including but not limited to: 1) the direct integration of the cooling solution on the die, which lessens the number of interfaces between the microelectronic die and heat dissipation device, as any interface will create a temperature gradient due to finite thermal conductivity, and 2) the enhanced thermoelectric properties of nano-wires due to reduced dimensionality can increase efficiency of the cooling solution, which, in turn, can reduce the required electrical power to extract similar amounts heat compared to known thermoelectric coolers.

The performance of a thermoelectric material both in cooling (the Peltier effect) and in generation (the Seebeck effect) is evaluated in terms of the dimensionless figure of merit “ZT” (T is the absolute temperature and Z=α²/(ρλ), where α is the Seebeck coefficient, ρ is the electrical resistivity, and λ is the thermal conductivity). Typical values of ZT for macroscopic elements are around 1. Generally, ZT is enhanced as the structural dimensions get lower. Values of 1.5 or greater can be achieved as the diameter of the wires of the present invention approach the nanometer scale. As will be understood to those skilled in the art, the selection of the nano-wire length may be based on the effective thermal conductivity of the dielectric layer and the thermoelectric performance of the nano-wires. This may be an optimizing operation and is dependent on the power, power map, and overall package resistance.

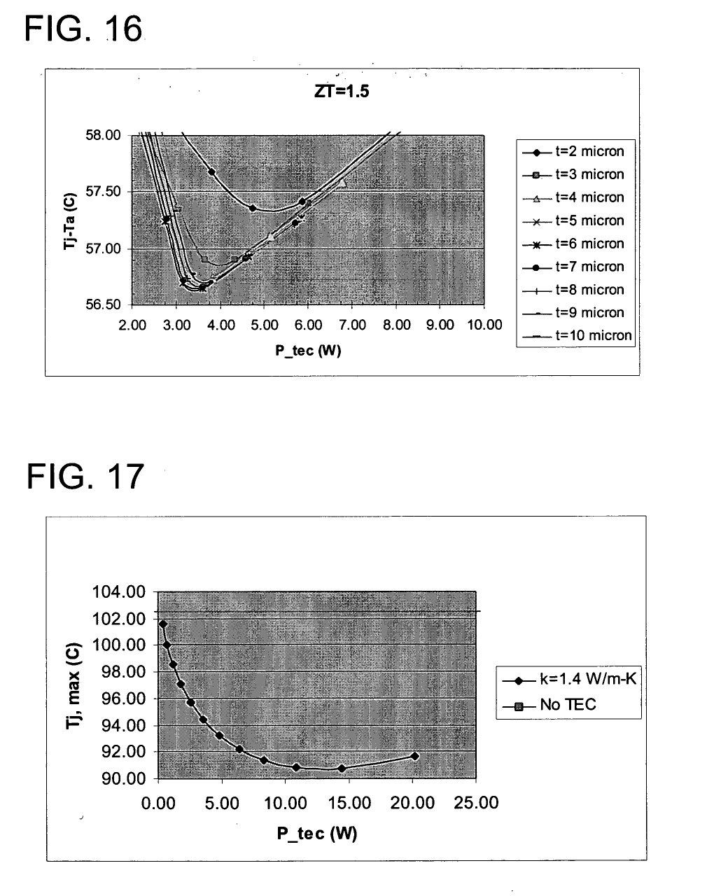

The performance of nano-scale thermoelectric wires can be modeled to determine the impact of enhanced ZT. FIGS. 15 and 16 show the temperature reduction achievable with nano-wires exhibiting a ZT of 1.0 and 1.5, respectively, over a range of power input as function of wire length. As shown in FIGS. 15 and 16, the use of nano-wires results in both greater reductions in the maximum temperature on the microelectronic die and lower power input required to achieve those lower temperatures. The wire length resulting in the greatest temperature reduction is also dependent on the ZT values of the nano-wires.

FIG. 17 illustrates a model of the benefit of using nano-wires in thermoelectric devices in conjunction with a copper heat spreader versus a copper heat spreader alone at a junction temperature (Tj) of about 102.5° C. With the use of the thermoelectric nano-wire device, a reduction injunction temperature of about 11.73° C. was realized, which is about an 11% temperature reduction. The model shown on FIG. 17 was generated with the parameters of a 1 square centimeter microelectronic die that was powered uniformly to 100 W/cm² including a 0.5 mm×0.5 mm “hotspot” in the center that was powered to 800 W/cm². A thermal interface material and a heat sink were modeled to contact the backside of the microelectronic die, and a thermoelectric nano-wire device was also modeled to contact the backside of the microelectronic die. The thermoelectric nano-wire device was modeled to measure 3 mm×3 mm and has elements which were 10 microns thick. The cross sectional area of the elements occupied 80% of the footprint area of the thermoelectric cooler (i.e., 80% of the 3 mm×3 mm footprint). The thermoelectric cooler's figure of merit “ZT” modeled to be 3 and the ambient temperature surrounding the microelectronic die was modeled to be 25° C.

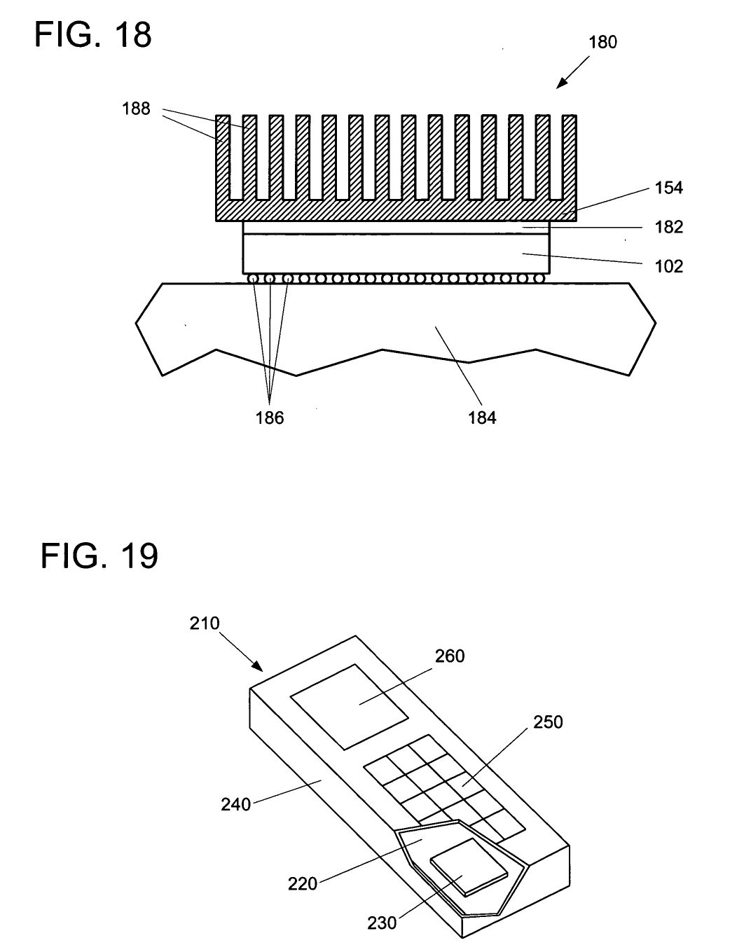

FIG. 18 illustrates a microelectronic assembly 180 of the present invention comprising a thermoelectric nano-wire device layer 182 (including the thermoelectric nano-wire device 140 (not shown) as previously described) on a microelectronic die 102 (illustrated as a flip chip). A heat dissipation device 154 can be placed in contact with the thermoelectric nano-wire device layer 182. The microelectronic die 102 may be physically and electrically attached to a substrate 184 by a plurality of solder balls 186. The heat dissipation device 154 may include a plurality of projections 188 extending therefrom. The projections 188 are generally molded during the formation of the heat dissipation device 102 or machined therein after formation. It is, of course, understood that the projections 188 may include, but are not limited to, elongate planar fin-like structures (extending perpendicular to the figure) and columnar/pillar structures.

The packages formed by the present invention may be used in a hand-held device 210, such as a cell phone or a personal data assistant (PDA), as shown in FIG. 19. The hand-held device 210 may comprise a device substrate 220 with at least one microelectronic device assembly 230, including but not limited to, a central processing units (CPUs), chipsets, memory devices, ASICs, and the like, having at least one thermoelectric nano-wire device 140 (not shown) and/or thermoelectric nano-wire device 170 (not shown), as described above, within a housing 240. The device substrate 220 may be attached to various peripheral devices including an input device, such as keypad 250, and a display device, such an LCD display 260.

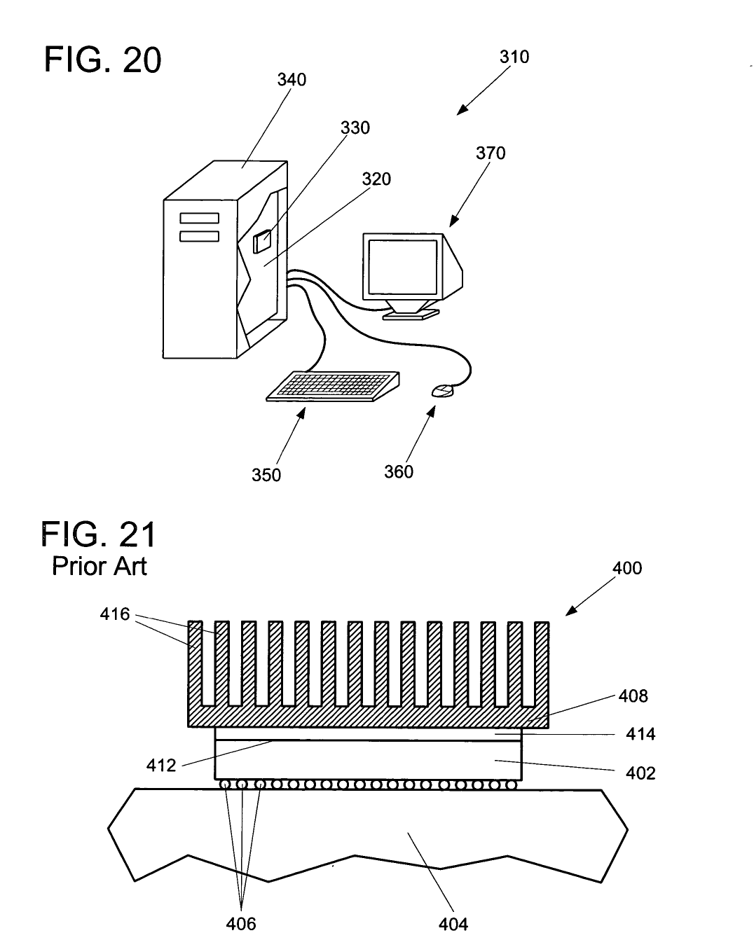

The microelectronic device assemblies formed by the present invention may also be used in a computer system 310, as shown in FIG. 20. The computer system 310 may comprise a device substrate or motherboard 320 with at least one microelectronic device assembly 330, including but not limited to, a central processing units (CPUs), chipsets, memory devices, ASICs, and the like, having at least one thermoelectric nano-wire device 140 (not shown) and/or thermoelectric nano-wire device 170 (not shown), as described above, within a housing or chassis 340. The device substrate or motherboard 320 may be attached to various peripheral devices including inputs devices, such as a keyboard 350 and/or a mouse 360, and a display device, such as a CRT monitor 370.

Having thus described in detail embodiments of the present invention, it is understood that the invention defined by the appended claims is not to be limited by particular details set forth in the above description, as many apparent variations thereof are possible without departing from the spirit or scope thereof.

1. A thermoelectric apparatus, comprising:
a first electrode;
a dielectric material proximate said first electrode;
a second electrode opposing said first electrode with said dielectric material deposed therebetween; and
at least one nano-wire extending between said first electrode and said second electrode.

2. The apparatus of claim 1, wherein said at least one nano-wire comprises a bismuth containing material.

3. The apparatus of claim 1, wherein said dielectric material comprises a porous dielectric material.

4. The apparatus of claim 3, wherein said porous dielectric material comprises porous alumina.

5. The apparatus of claim 1, further comprising a negatively charged trace electrically connected to said first electrode and a positively charged trace to said second electrode.

6. A thermoelectric package, comprising:
a microelectronic die having at least one area of which is of a higher heat dissipation rate than the remainder of the microelectronic die when in operation;
a first electrode proximate said microelectronic die including said higher heat area;
a dielectric material proximate said first electrode;
a second electrode opposing said first electrode with said dielectric material disposed therebetween; and
a plurality of nano-wires extending between said first electrode and said second electrode.

7. The package of claim 6, wherein said nano-wires are dispersed in a higher density proximate said at least one higher heat dissipation rate area.

8. The package of claim 6, wherein said at least one nano-wire comprises a bismuth containing material.

9. The package of claim 6, wherein said dielectric material comprises a porous dielectric material.

10. The package of claim 9, wherein said porous dielectric material comprises porous alumina.

11. The package of claim 6, further comprising a negatively charged trace electrically connected to said first electrode and a positively charged trace to said second electrode.

12. A method comprising:
providing a first electrode;
disposing a dielectric material proximate said first electrode;
forming at least one nano-scale opening through the dielectric material;
disposing a conductive material within said at least one nano-scale opening to form at least one nano-wire which contacts said first electrode; and
forming a second electrode opposing said first electrode with said dielectric material deposed therebetween, wherein said second electrode contacts said at least one nano-wire.

13. The method of claim 12, wherein disposing said conductive material comprising disposing a bismuth containing material.

14. The method of claim 12, wherein disposing said dielectric material comprises disposing a porous dielectric material.

15. The method of claim 14, wherein disposing said porous dielectric material comprises disposing porous alumina.

16. The method of claim 12, further comprising forming a negatively charged trace electrically connected to said first electrode and forming a positively charged trace to said second electrode.

17. A method comprising:
providing a first electrode;
disposing a porous dielectric material proximate said first electrode;
disposing a conductive material on said porous dielectric material, wherein said conductive material extends through at least one opening in said porous material to form at least one nano-wire which contacts said first electrode; and
forming a second electrode opposing said first electrode with said dielectric material deposed therebetween, wherein said second electrode contacts said at least one nano-wire.

18. The method of claim 17, wherein disposing said conductive material on said porous dielectric material comprises disposing a bismuth containing material on said porous dielectric material.

19. The method of claim 19, wherein disposing said porous dielectric material comprises disposing porous alumina.

20. The method of claim 17, further comprising forming a negatively charged trace electrically connected to said first electrode and forming a positively charged trace to said second electrode.

21. An electronic system, comprising:
an external substrate within a housing; and
at least one microelectronic device package attached to said external substrate, having at least thermoelectric device including:
a first electrode;
a dielectric material proximate said first electrode;
a second electrode opposing said first electrode with said dielectric material deposed therebetween; and
at least one nano-wire extending between said first electrode and said second electrode;
an input device interfaced with said external substrate; and
a display device interfaced with said external substrate.

22. The system of claim 21, wherein said at least one nano-wire comprises a bismuth containing material.

23. The system of claim 21, wherein said dielectric material comprises a porous dielectric material.

24. The system of claim 23, wherein said porous dielectric material comprises porous alumina.

25. The system of claim 21, wherein said thermoelectric device further comprises a negatively charged trace electrically connected to said first electrode and a positively charged trace to said second electrode.
